(19) United States
(12) Patent Application Publication
(10) Pub. No.: US 2021/0084770 A1
(43) Pub. Date: Mar. 18, 2021

(54) CONFORMAL COATING FOR ELECTRONIC DEVICES AND METHODS OF COATING

(71) Applicant: HONEYWELL FEDERAL MANUFACTURING & TECHNOLOGIES, LLC, Kansas City, MO (US)

(72) Inventors: Mark M. Swartz, Kansas City, MO (US); Michael Walsh, Overland Park, KS (US)

(73) Assignee: HONEYWELL FEDERAL MANUFACTURING & TECHNOLOGIES, LLC, KANSAS CITY, MO (US)

(21) Appl. No.: 17/016,485

(22) Filed: Sep. 10, 2020

Related U.S. Application Data
(60) Provisional application No. 62/899,857, filed on Sep. 13, 2019.

(51) Int. Cl. H05K 3/12; H05K 1/09; H01Q 1/38

(52) U.S. Cl. CPC H05K 3/1283; H05K 2201/0215; H01Q 1/38; H05K 1/092

(57) ABSTRACT

A method of forming an electronic circuit component comprises (a) depositing nanoparticle ink comprising conductive material on a substrate; (b) curing the nanoparticle ink to form cured nanoparticle ink; (c) subjecting the cured nanoparticle ink to a first precursor gas to form a first layer of precursor material on the cured nanoparticle ink; and (d) subjecting the first layer of precursor material to a second precursor gas so that the first layer of precursor material reacts with the second precursor gas to form an oxide layer on the cured nanoparticle ink.

### RELATED APPLICATIONS

This application claims the benefit of U.S. Provisional Application Ser. No. 62/899,857, filed Sep. 13, 2019, entitled CONFORMAL COATING FOR ELECTRONIC DEVICES AND METHODS OF COATING, the entire disclosure of which is hereby incorporated by reference herein.

### STATEMENT REGARDING FEDERALLY-SPONSORED RESEARCH OR DEVELOPMENT

This invention was made with Government support under Contract No.: DE-NA-0002839 awarded by the United States Department of Energy/National Nuclear Security Administration. The Government has certain rights in the invention.

### BACKGROUND

Many electronic circuits and devices have conductors and other exposed metal components formed with printed metal inks. The exposed metal may include circuit traces, conductive paths, radio-frequency identification (RFID) tags, antennas, etc. The exposed metal often has a relatively large surface area that is susceptible to oxidation and corrosion, which is detrimental to electrical performance and longevity. Additionally, exposed metal formed by nanoparticle inks are often exposed to corrosive liquids and gases, which can further deteriorate the components.

The background discussion is intended to provide information related to the present invention which is not necessarily prior art.

### SUMMARY

The present invention solves the above-described problems and other problems and provides a distinct advance in the art of nanoparticle printing. More particularly, embodiments of the present invention provide methods for precise coating of conductive material formed with nanoparticle ink.

A method of forming an electronic circuit component according to an embodiment of the present invention broadly comprises (a) depositing nanoparticle ink comprising conductive material on a substrate; (b) curing the nanoparticle ink to form cured nanoparticle ink; (c) subjecting the cured nanoparticle ink to a first precursor gas to form a first layer of precursor material on the cured nanoparticle ink; and (d) subjecting the first layer of precursor material to a second precursor gas so that the first layer of precursor material reacts with the second precursor gas to form an oxide layer on the cured nanoparticle ink.

In some embodiments, the method may further comprise repeating steps (c) and (d) with the same precursor gases or different precursor gases until the one or more oxide layers is at a desired thickness to protect the nanoparticle ink. This allows small structures formed with nanoparticle ink to be completely protected in a precise manner and without any pin holes.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the present invention will be apparent from the following detailed description of the embodiments and the accompanying drawing figures.

### BRIEF DESCRIPTION OF THE DRAWING FIGURES

Embodiments of the present invention are described in detail below with reference to the attached drawing figures, wherein:

FIG. 1A is a perspective view of an example antenna structure with which principles of the present invention may be implemented;

FIG. 1B is a perspective view of an example circuit structure with which principles of the present invention may be implemented;

FIG. 2 is a schematic diagram of an atomic layer deposition system with which principles of the present invention may be implemented;

FIG. 3 is a side sectional view of a circuit component with an oxide layer formed according to embodiments of the present invention;

FIG. 4 is a side sectional view of a circuit component formed with multiple oxide layers according to embodiments of the present invention; and

FIG. 5 is a flowchart illustrating at least a portion of the steps for forming an electronic component according to an embodiment of the present invention.

The drawing figures do not limit the present invention to the specific embodiments disclosed and described herein. The drawings are not necessarily to scale, emphasis instead being placed upon clearly illustrating the principles of the invention.

### DETAILED DESCRIPTION OF THE EMBODIMENTS

The following detailed description of the invention references the accompanying drawings that illustrate specific embodiments in which the invention can be practiced. The embodiments are intended to describe aspects of the invention in sufficient detail to enable those skilled in the art to practice the invention. Other embodiments can be utilized and changes can be made without departing from the scope of the present invention. The following detailed description is, therefore, not to be taken in a limiting sense. The scope of the present invention is defined only by the appended claims, along with the full scope of equivalents to which such claims are entitled.

In this description, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the present technology can include a variety of combinations and/or integrations of the embodiments described herein.

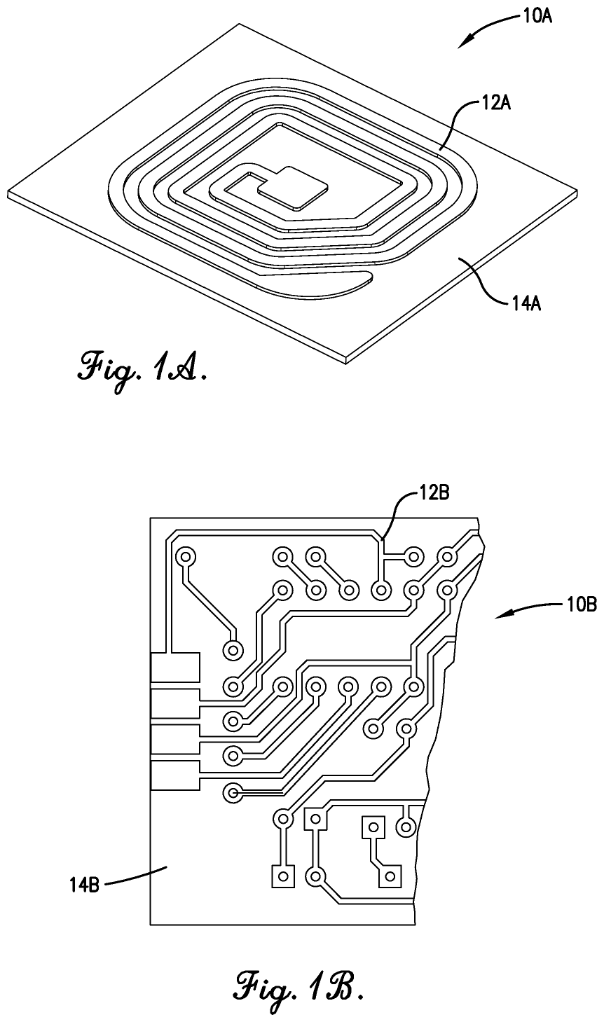

Embodiments of the present invention comprise methods of forming coated circuit components 10A, 10B comprising conductive material 12A, 12B formed with nanoparticle ink. As depicted in FIGS. 1A and 1B, the nanoparticle ink may be deposited to form various structures, such as antennas (as depicted in FIG. 1A), circuit traces (as depicted in FIG. 1B), buses, radio frequency identification tags, portions of conductive pads for surface mounted devices, portions of via pads, etc. The conductive material 12A, 12B may be formed by depositing nanoparticle ink on a substrate 14A, 14B for high precision formation of said components 10A, 10B. The nanoparticle ink may include copper, silver, gold, platinum, and/or other conductive material. The nanoparticle ink may deposited via a printer having an extrusion needle or the like. The substrates 14A, 14B may comprise a dielectric layer, glass-reinforced epoxy, plastic, and/or other materials.

Exposed nanoparticle ink is prone to corrosion and oxidation, which can be detrimental to the performance of the circuit components 10A, 10B. Because many applications using nanoparticle ink involve precise and relatively small structures, current solutions for protecting circuit components 10A, 10B from corrosion and oxidation are limited.

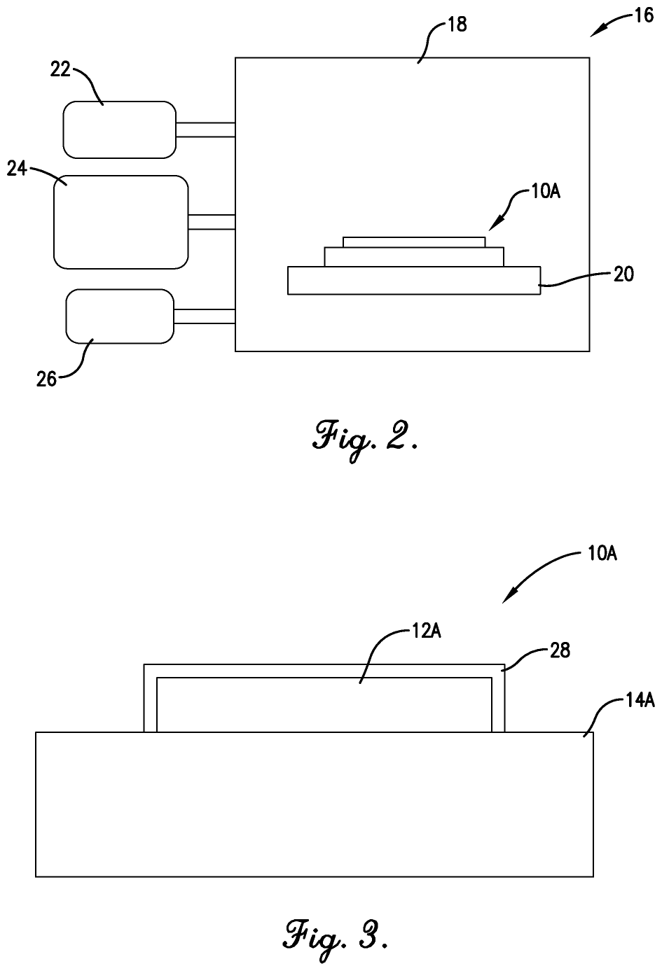

Turning to FIG. 2, a system 16 for implementing principles of the present invention is schematically depicted. The system 16 is configured to perform atomic layer deposition (ALD) on a circuit component, such as circuit component 10A, so that the conductive material 12A formed with nanoparticle ink may be coated with a material with a precise thickness. For example, the nanoparticle ink may be coated with one or more layers of aluminum oxide (Al₂O₃), titanium oxide (TiO₂), hafnium oxide (HfO), and/or hafnium dioxide (HfO₂). The different layers of oxide may be the same type of oxide or different types, such as alternating layers of different types of oxides. The thickness of one or more of the layers may be about 10 nanometers (nm) to about 100 nm. The system 16 may comprise a chamber 18, a platform 20 inside the chamber 18, and a plurality of gas sources 22, 24, 26 in fluid communication with the chamber 18.

The chamber 18 is configured to facilitate the ALD process therein. The platform 20 is operable to support the circuit component 10A in the chamber 18. The gas sources 22, 24, 26 may store different gases used in the ALD process. For example, one of the gas sources 22 may store a first precursor gas, one of the gas sources 26 may store a second precursor gas, and one of the gas sources 24 may store a carrier gas. The precursor gases vary depending on the desired oxide to be formed on the conductive material 12A of the circuit component 10A. For example, to form Al₂O₃, the first precursor gas may comprise trimethyl aluminum and the second precursor gas may comprise water. The carrier gas may comprise an inert gas, such as argon, nitrogen, etc.

The system 16 may be configured to direct the first precursor gas into the chamber 18 to subject the conductive material 12A to the first precursor gas and form a first layer of precursor gas material on the conductive material 12A. The carrier gas may then be directed into the chamber 18 to purge the chamber 18 of remaining first precursor gas. The second precursor gas may then be directed into the chamber 18 to subject the first layer of precursor gas material to the second precursor gas. The first layer of precursor gas material may react with the second precursor gas to form a first layer of oxide material 28, as depicted in FIG. 3. The carrier gas may then be directed into the chamber 18 to purge remaining second precursor gas.

The system 16 may be configured to repeat this process one or more times forming multiple layers of oxide 30, 32, 34, as depicted in FIG. 4, until the oxide on the conductive material 12A is at a desired thickness. The system 16 may include additional gas sources for introducing one or more different types of precursor gases into the chamber 18 for forming different types of oxides on the conductive material 12A. For example, oxide layer 30 may comprise a different type of oxide as oxide layer 32 but the same type of oxide as oxide layer 34. Each layer may have a thickness of about 10 nm.

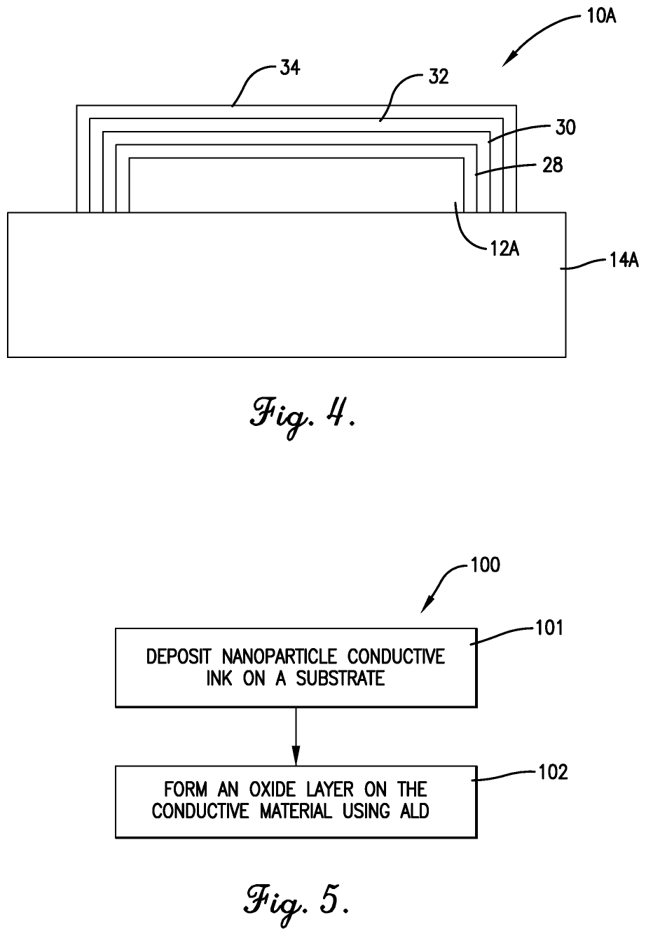

Turning to FIG. 5, the flow chart depicts the steps of an exemplary method 100 of forming a coated circuit component according to an embodiment of the present invention. In some alternative implementations, the functions noted in the various blocks may occur out of the order depicted in FIG. 5. For example, two blocks shown in succession in FIG. 5 may in fact be executed substantially concurrently, or the blocks may sometimes be executed in the reverse order depending upon the functionality involved. In addition, some steps may be optional.

The method 100 is described below, for ease of reference, as being executed by exemplary devices and components introduced with the embodiments illustrated in FIGS. 1-4. However, some of such actions may be distributed differently among such devices or other devices without departing from the spirit of the present invention.

Referring to step 101, nanoparticle ink is deposited on a substrate to form a circuit component. The nanoparticle ink may comprise copper, silver, gold, platinum, and/or other conductive material and may be deposited via an extrusion needle or the like. The substrate may comprise dielectric layer, glass-reinforced epoxy, plastic, and/or other materials. The nanoparticle ink may be deposited to form an antenna, a circuit trace, a bus, a radio frequency identification tag, a portion of a conductive pad for a surface mounted device, a portion of a via pad, or the like. This step 101 may include curing the nanoparticle ink.

Referring to step 102, a first oxide layer is formed on an exposed portion of the deposited nanoparticle ink via ALD. The oxide layer may have a thickness of 10 nm up to 100 nm, or greater, and may include Al₂O₃, TiO₂, HfO, and/or HfO₂. The oxide layer formed via ALD provides a coating that is conformal to the exposed portion of the nanoparticle ink and maintains electrical performance of the component even after long periods of time and under adverse environmental conditions. This step may include directing a first precursor gas into a chamber, or otherwise at the substrate, to subject the nanoparticle ink to the first precursor gas and form a first layer of precursor gas material on the nanoparticle ink. A carrier gas may be directed into the chamber to purge the chamber of remaining first precursor gas. A second precursor gas may be directed into the chamber, or otherwise at the substrate, to subject the first layer of precursor gas material to the second precursor gas. The first layer of precursor gas material may react with the second precursor gas to form a first layer of oxide material. The carrier gas may be directed into the chamber to purge remaining second precursor gas.

The method 100 may include additional, less, or alternate steps and/or device(s), including those discussed elsewhere herein. For example, the method 100 may further include repeating step 102 one or more times to form multiple layers of oxide until the oxide on the nanoparticle ink is at a desired thickness. This may include directing one or more different types of precursor gases into the chamber, or otherwise at the substrate, for forming different types of oxides on the nanoparticle ink. For example, each layer of oxide may comprise a different type of oxide. In some embodiments, each layer of oxide may be the same type of oxide. Each layer may have a thickness of about 10 nm.

### Additional Considerations

In this description, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the current technology can include a variety of combinations and/or integrations of the embodiments described herein.

Although the present application sets forth a detailed description of numerous different embodiments, it should be understood that the legal scope of the description is defined by the words of the claims set forth at the end of this patent and equivalents. The detailed description is to be construed as exemplary only and does not describe every possible embodiment since describing every possible embodiment would be impractical. Numerous alternative embodiments may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

The various operations of example methods described herein may be performed, at least partially, by one or more processing elements that are temporarily configured (e.g., by software) or permanently configured to perform the relevant operations. Whether temporarily or permanently configured, such processing elements may constitute processing element-implemented modules that operate to perform one or more operations or functions. The modules referred to herein may, in some example embodiments, comprise processing element-implemented modules.

Similarly, the methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

Although the invention has been described with reference to the embodiments illustrated in the attached drawing figures, it is noted that equivalents may be employed and substitutions made herein without departing from the scope of the invention as recited in the claims.

Having thus described various embodiments of the invention, what is claimed as new and desired to be protected by Letters Patent includes the following:

1. A method of forming an electronic circuit component, the method comprising:
(a) depositing nanoparticle ink comprising conductive material on a substrate;
(b) curing the nanoparticle ink to form cured nanoparticle ink;
(c) subjecting the cured nanoparticle ink to a first precursor gas to form a first layer of precursor material on the cured nanoparticle ink; and
(d) subjecting the first layer of precursor material to a second precursor gas so that the first layer of precursor material reacts with the second precursor gas to form an oxide layer on the cured nanoparticle ink.

2. The method of claim 1, wherein step (a) comprises extruding the nanoparticle ink through an extrusion needle.

3. The method of claim 1, wherein the oxide layer has a thickness from about 10 nm to about 100 nm.

4. The method of claim 1, wherein the oxide layer has a thickness from about 10 nm to about 50 nm.

5. The method of claim 1, wherein the substrate comprises at least one of a dielectric layer, glass-reinforced epoxy, or plastic.

6. The method of claim 1, wherein step (a) comprises depositing the nanoparticle ink to form a conductive trace.

7. The method of claim 1, wherein the oxide layer comprises at least one of aluminum oxide (Al₂O₃), titanium oxide (TiO₂), hafnium oxide (HfO), or hafnium dioxide (HfO₂).

8. The method of claim 1, wherein the oxide layer is a first oxide layer, further comprising repeating steps (c) and (d) to form a second oxide layer on the first oxide layer.

9. The method of claim 1, wherein the oxide layer is a first oxide layer, further comprising—
(e) subjecting the first oxide layer to a third precursor gas to form a second layer of precursor material; and
(f) subjecting the second layer of precursor material to a fourth precursor gas so that the second layer of precursor material reacts with the fourth precursor gas to form a second oxide layer on the first oxide layer, wherein the second oxide layer is a different type of oxide than the first oxide layer.

10. The method of claim 1, further comprising subjecting the first layer of precursor material to a carrier gas before step (d).

11. The method of claim 10, wherein the carrier gas comprises an inert gas.

12. The method of claim 1, wherein the conductive material comprises at least one of copper, silver, gold, or platinum.

13. The method of claim 1, wherein step (a) comprises depositing the nanoparticle ink to form an antenna.

14. A method of forming an electronic circuit component, the method comprising:
(a) depositing nanoparticle ink comprising conductive material on a substrate;
(b) subjecting the nanoparticle ink to a first precursor gas to form a layer of precursor material;
(c) subjecting the layer of precursor material to a second precursor gas so that the first layer of precursor material reacts with the second precursor gas to form an oxide layer on the nanoparticle ink; and
(d) repeating steps (b) and (c) until the oxide layer on the nanoparticle ink is at a desired thickness.

15. The method of claim 14, wherein the oxide layer comprises at least one of aluminum oxide (Al₂O₃), titanium oxide (TiO₂), hafnium oxide (HfO), or hafnium dioxide (HfO₂).

16. The method of claim 14, wherein the nanoparticle ink forms a conductive trace on the substrate.

17. A method of forming an electronic circuit component, the method comprising:
(a) depositing nanoparticle ink comprising conductive material on a substrate;
(b) curing the nanoparticle ink;
(c) subjecting the nanoparticle ink to a first precursor gas to form a first layer of precursor material on the nanoparticle ink;
(d) subjecting the first layer of precursor material to a second precursor gas so that the first layer of precursor material reacts with the second precursor gas to form a first oxide layer on the nanoparticle ink;
(e) subjecting the first oxide layer to a third precursor gas to form a second layer of precursor material on the first oxide layer; and
(f) subjecting the second layer of precursor material to a fourth precursor gas so that the second layer of precursor material reacts with the fourth precursor gas to form a second oxide layer on the first oxide layer, wherein the first oxide layer is a different type of oxide than the second oxide layer.

18. The method of claim 17, wherein first oxide comprises at least one of aluminum oxide (Al₂O₃), titanium oxide (TiO₂), hafnium oxide (HfO), or hafnium dioxide (HfO₂).

19. The method of claim 17, wherein the first oxide layer has a thickness of about 10 nm to about 100 nm.

20. The method of claim 17, wherein the nanoparticle ink forms an antenna.
